(19) United States
(12) Patent Application Publication
(10) Pub. No.: US 2023/0396016 A1
(43) Pub. Date: Dec. 7, 2023

(54) COOLING SYSTEM FOR A PERSONAL COMPUTER

(71) Applicant: EKWB d.o.o., Komenda (SI)

(72) Inventor: Edvard König, Log pri Brezovici (SI)

(73) Assignee: EKWB d.o.o., Komenda (SI)

(21) Appl. No.: 17/948,598

(22) Filed: Sep. 20, 2022

(30) Foreign Application Priority Data
Jun. 1, 2022 (DE) 20 2022 103 104.5

(51) Int. Cl. H01R 13/533; H05K 7/20; G06F 1/20

(52) U.S. Cl. CPC H01R 13/533; H05K 7/20272; G06F 1/203

(57) ABSTRACT

A cooling system for a personal computer includes at least one cooling device using electrical power, and a wiring. The wiring has a male connector, a female connector, at least one first wire arrangement, and at least one second wire arrangement. The first and second wire arrangements electrically connect the male connector to the cooling device, the female connector to the cooling device, and the male connector to the female connector. The first wire arrangement is configured to electrically connect the cooling device to a ground, and the second wire arrangement is configured to electrically connect the cooling device to a power supply.

### CROSS-REFERENCE TO RELATED APPLICATION

This application claims priority to German application DE 20 2022 103 104.5, filed Jun. 1, 2022.

### TECHNICAL FIELD

The invention relates to a cooling system for a personal computer.

### BACKGROUND

Personal computers comprise cooling devices such as fans or coolant pumps for managing heat inside a case of the personal computer. The cooling devices may comprise lighting elements, for example RGB or A-RGB lighting elements, as decorative elements.

Electrical power for the cooling devices and the lighting elements is provided by a power supply unit (PSU) or via the mother board of the computer. Typically, in order to connect the PSU and/or the mother board to multiple cooling devices and lighting elements inside a single computer case, cable splitters are used. The cable splitters are connected at one end to the PSU or the mother board and fan out into multiple cables, each cable of the cable splitter connecting to a single cooling device or lighting element. Further, the lighting elements need additional cables for receiving control signals resulting in additional clutter inside the computer case.

It is desirable to hide cables inside the computer case, for example in order to improve airflow inside the case or for aesthetic reasons. However, in the existing solution mentioned above, the cooling devices and the lighting elements each have their own separate cable that connects to the PSU or to the mother board. This results in a cluttered computer case. Accordingly, the existing solutions make it all the more difficult to hide the cables, the more cooling devices, lighting elements etc. need to be connected.

### BRIEF DESCRIPTION

It is therefore an object to provide a cooling system for a personal computer that reduces cable clutter inside a case of the personal computer.

The aforementioned object is achieved by the subject-matter of the independent claims. Advantageous embodiments are defined in the dependent claims and the following description.

The proposed cooling system for a personal computer comprises at least one cooling device using electrical power and having a body and a wiring. The wiring comprises a male connector, a female connector, at least one first wire arrangement, and at least one second wire arrangement. The first and second wire arrangements electrically connect the male connector to the body of the cooling device, the female connector to the body of the cooling device, and the male connector to the female connector. The first wire arrangement is configured to electrically connect the cooling device to a ground, and the second wire arrangement is configured to electrically connect the cooling device to a power supply.

In a personal computer the power supply typically supplies electrical current to cooling devices at 12 V. A voltage of 12 V is an appropriate voltage for most fans and coolant pumps. Some cooling device require an even higher voltage of 24 V. The wires of the first and second wire arrangements need to be chosen accordingly.

One of the two connectors of the wiring can be connected to the power supply providing electrical power to the cooling device. The other connector can be connected to another cooling device, thereby providing electrical power to the other cooling device. Additional cooling devices may be connected thereafter. In this manner, it is possible to connect a number of cooling devices in series. Known arrangements would use cable splitters and individual cables running from the power supply to the cooling devices. Contrary thereto, in the proposed cooling system, there is only one cable running from the power supply to the last cooling device supplying electrical power to all connected cooling devices. Thus, compared to known arrangements cable clutter is greatly reduced. This allows a user to easily hide the cables which improves the airflow inside a computer case, thus making the cooling system also more efficient.

In a preferred embodiment, the wiring is arranged in a T-shape or an L-shape comprising a first line of wires between the male connector and the female connector, and a second line of wires extending from the first line of wires and connecting the first line of wires with the body of the cooling device. When connecting several cooling devices in series, the first lines form a single continuous line of wires between the first and the last cooling device in the series. This single line can easily be routed and hidden. Thus, the T-shape or the L-shape makes it very easy to connect cooling devices arranged next to each other. In order to electrically connect the first line of wires and the second line of wires, the first line of wires and the second line of wires may for example be connect at the male connector and/or the female connector. Alternatively, the wiring may form a triangle, a Y-shape or a V-shape between the male connector, the female connector, and the body of the cooling device.

In another preferred embodiment, the cooling device comprises a fan. The second wire arrangement is configured to electrically connect the fan to the power supply. Fans manage heat inside a computer case by exhausting hot air. For example, a fan may blow cold air directly onto a heat producing element or onto a heat exchanger connected to a heat generating element, allowing the heat generating element to cool off. Compared to other cooling devices fans are very cost effective. In this embodiment, the first line of wires may be equal in length to a housing of the fan. Thereby, reducing the amount of loose wire resulting in even less cable clutter.

In another preferred embodiment, the wiring comprises at least one third wire arrangement, and at least one fourth wire arrangement. The third wire arrangement electrically connects the male connector to the cooling device, the fourth wire arrangement electrically connects the male connector to the cooling device, the female connector to the cooling device, and the male connector to the female connector. The third wire arrangement is configured to electrically connect the cooling device to a fan control unit, and to transmit a tachometer signal of a speed sensor of the fan to the fan control unit. The fourth wire arrangement is configured to electrically connect the cooling device to the fan control unit, and to transmit a pulse width modulation signal from the fan control unit to the fan. Alternatively, the third wire arrangement may connect the female connector to the cooling device.

In this embodiment, the fan is a so called 4-pin or pulse width modulation (PWM) fan. A rotational speed of the fan can be adjusted by modifying the duty cycle of the pulse width modulation signal, thereby modifying the average value of voltage supplied to the fan. The tachometer signal from the speed sensor of the fans gives feedback to the fan control unit about the rotational speed of the fan. Thus, the fan control unit is configured to precisely control the fan speed, for example based on a temperature of a heat generating element inside the case of the personal computer. In particular, the fan speed can be reduced when less cooling is needed. Since all fans produce noise at high rotational speeds, this greatly reduces the noise due to cooling.

In an alternative embodiment, the wiring does not comprise the fourth wire arrangement for connecting the cooling device to the fan control unit for controlling a pulse width modulation of the fan. In this embodiment, the fan is a so called 3-pin fan. The rotational speed of the fan is controlled by adjusted the voltage of the electrical current supplied to the fan. However, since all fans have a minimum operating voltage, it is not possible to operate 3-pin fans at very low speeds. They are therefore noisier than PWM fans.

In another preferred embodiment, the cooling device comprises a coolant pump configured to pump a liquid coolant; and wherein the second wire arrangement is configured to electrically connect the coolant pump to the power supply. In this embodiment, the cooling device is a liquid cooling device. Whereas fans use air as a coolant medium, the liquid cooling device uses a liquid coolant medium, for example water. The coolant pump moves the coolant medium between a first heat exchanger thermally connected to a heat generating element, and a second heat exchanger thermally connected to a large heat sink, for example the outside air. Thereby, heat is removed from the heat generating element. Compared to other cooling devices a liquid cooling device is highly efficient and produces very little noise.

In another preferred embodiment, the cooling device comprises a lighting unit configured to illuminate the cooling device. The wiring comprises at least one fifth wire arrangement. The fifth wire arrangement connects the male connector to the lighting unit, the female connector to the lighting unit, and the male connector to the female connector. The fifth wire arrangement is configured to electrically connect the lighting unit to a second power supply. The lighting elements is a decorative element that makes the otherwise bland computer case more visually appealing. The lighting element may for example comprise one or more LED elements in different colors in order to provide a colorful illumination of the inside of the computer case. Lighting elements typically require electrical current at either 5 V or 12 V. The wires of the fifth wire arrangement need to be chosen accordingly.

In another preferred embodiment, the lighting unit is configured for A-RGB lighting, to receive a digital input signal for controlling the A-RGB lighting, and to provide a digital output signal. A-RBG lighting is also called addressable RGB or digital RGB (D-RBG). The wiring comprises at least one sixth wire arrangement, at least one seventh wire arrangement, and at least one eighth wire arrangement. The sixth wire arrangement is configured to electrically connect the lighting unit to a lighting control unit configured to provide the digital input signal. The seventh wire arrangement is configured to electrically connect the lighting unit to a target of the digital output signal. The eighth wire arrangement is configured to electrically connect the lighting unit to the ground. The sixth wire arrangement may be connected the male connector and the seventh wire arrangement may be may be connected the female connector. Alternatively, the sixth wire arrangement may be connected the female connector and the seventh wire arrangement may be may be connected the male connector. Both the sixth and the seventh wire arrangements are electrically connected to the lighting unit. The eighth wire arrangement connects the male connector to the lighting unit, the female connector to the lighting unit, and the male connector to the female connector.

In this embodiment, the lighting unit comprises at least three light sources, for example LED elements, configured to provide red light, green light, and blue light, respectively. By mixing the three different light colors, many different colors can be generated. The lighting unit is controlled by the digital input signal generated by the lighting control unit. The lighting unit may pass the digital input signal unchanged as the digital output signal. In this configuration the lighting units of all cooling devices connected in series receive the same digital input signal. In order to send a different control signal to different cooling devices, the digital input signal may be multiplexed. Alternatively, the lighting unit may be configured to generate the digital output signal by modifying the digital input signal. Since the control signal is a digital signal, A-RGB lighting provides a very detailed control over the lighting colors and effects. Further, only one signal line is needed for controlling the three light sources with the digital input signal. This further reduces cable clutter.

In another preferred embodiment, the lighting unit is configured for RGB lighting, and to receive a first input signal for controlling a red element of the RGB lighting, a second input signal for controlling a green element of the RGB lighting, and a third input signal for controlling a blue element of the RGB lighting. The wiring comprises at least one ninth wire arrangement, at least one tenth wire arrangement, and at least one eleventh wire arrangement. The ninth wire arrangement is configured to electrically connect the lighting unit to a lighting control unit configured to provide the first input signal. The tenth wire arrangement is configured to electrically connect the lighting unit to a lighting control unit configured to provide the second input signal. The eleventh wire arrangement is configured to electrically connect the lighting unit to a lighting control unit configured to provide the third input signal.

As in the previously mentioned embodiment, the lighting unit comprises at least three light sources, for example LED elements, configured to provide red light, green light, and blue light, respectively. However, in this embodiment, the input signals are analogue signals and the different light sources are each controlled by one of the input signal. The input signals can be varied between the voltage level of the supply voltage, i.e. the current provided via the fifth wire arrangement, and a voltage level lower than that, typically 0 V or a negative voltage. When the voltage level of the input signal is set to the voltage level of the supply voltage, no current flows and the respective light source emits no light. When the voltage level of the input signal is set to a voltage level lower than that of the supply voltage, current flows and the respective light source emits light. A brightness of the individual light sources may be controlled by modulating the pulse width of the respective input signal. In this embodiment, the lighting units of all cooling devices connected in series receive the same input signals. However, compared to other lighting schemes, RGB lighting is easy to set up and does not require a lighting control unit capable of generating a digital signal, making this embodiment more cost effective.

In another preferred embodiment, the cooling system comprises a cable having a first connector configured to connect either to the female connector of the wiring or to connect to male connector of the wiring, a second connector configured to connect to at least the first power supply, and third connector configured to connect to the lighting control unit. The first power supply provides electrical power for example to the fan or the coolant pump. The second power supply provides electrical power to the lighting unit. Cooling devices, in particular fans, may be arranged at any location inside the case of the personal computer while the first and second power supplies are typically located at or near the mother board. The cable according to this embodiment provides an extension to connect an arrangement of cooling devices to the first and second power supplies as well as the lighting control unit.

The second connector may also be configured to connect to the second power supply. Typically, the second power supply and the lighting control unit are one structural element. For example, the second power supply may be integrated into the lighting control unit or the lighting control unit may pass electrical current from a PSU. Thus, it may be sufficient to provide one connector to connect to the second power supply and to the lighting control unit.

In another preferred embodiment, the second connector is a SATA power connector. SATA is a standard widely used in personal computers. The power line of a SATA connection provides electrical current at voltages of 5 V and 12 V. SATA is typically used for connecting mass storage devices and is available in any modern personal computer. Using electrical power provided by a SATA connector, typically located on the mother board, is therefore an efficient way of providing electrical power to the cooling device. In particular, when many cooling devices are used.

In another preferred embodiment, the cable comprises a fourth connector configured to connect to the fan control unit. Alternatively, the second connector may be configured to connect to the first power supply and to the fan control unit. Since the first power supply and the fan control unit are typically one structural element, it is sufficient to provide one connector to connect to the first power supply and to the fan control unit.

In another preferred embodiment, the cooling system comprises a cable having a male connector configured to connect to the female connector of the wiring, and a female connector configured to connect to the male connector of the wiring. The cable according to this embodiment provides an extension between two different cooling devices of the cooling system. This way, the cooling devices may be located at distant locations inside the case of the personal computer. Accordingly, the first line of wires between the male connector and the female connector may be short in length.

In another preferred embodiment, the cooling system comprises a controller configured to send the pulse width modulation signal and to receive the tachometer signal. The controller may also be configured to send the digital input signal. Further, the controller may comprise the first power supply and/or the second power supply. In these embodiments, the cooling system is a self-sufficient unit requiring no external input.

### BRIEF DESCRIPTION OF THE DRAWINGS

Hereinafter, specific embodiments are described referring to the drawings, wherein:

FIG. 1 is a schematic view of a cooling device according to an embodiment;

FIG. 2 is a schematic oblique top view of the cooling device according to FIG. 1;

FIG. 3 is a schematic top view of the cooling device according to FIG. 2;

FIG. 4 is a schematic view of the wiring of the cooling device according to FIGS. 1 to 3;

FIG. 5 is a schematic view of a wiring of a cooling device according to an embodiment;

FIG. 6 is a schematic view of a wiring of a cooling device according to another embodiment;

FIG. 7 is a schematic view of a cooling system for a personal computer according to an embodiment;

FIG. 8 is a schematic view of a cable of the cooling system according to FIG. 7;

FIG. 9 is a schematic view of another cable of the cooling system according to FIG. 7;

FIG. 10 is a schematic view of another cable of the cooling system according to FIG. 7; and

FIG. 11 is a schematic view of a cable of the cooling system according to FIG. 7.

### DETAILED DESCRIPTION

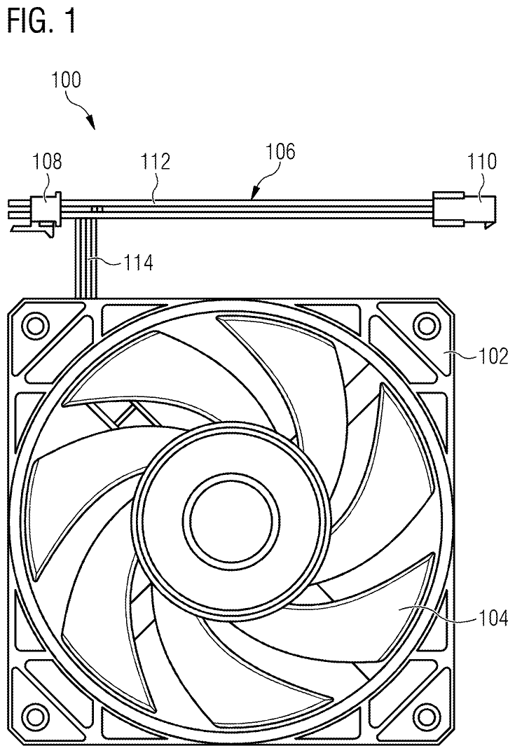

FIG. 1 is a schematic view of a cooling device 100 according to an embodiment.

The cooling device 100 according to the present embodiment is exemplary formed as a fan. The cooling device 100 comprises a fan body 102 and a fan blade 104. The fan body 102 comprises an electrical drive (hidden by the fan blade 104 in FIG. 1) configured to rotate the fan blade 104. The fan blade 104 is rotatably mounted on the fan body 102. The cooling device 100 is configured to manage heat inside a case of a personal computer by exhausting hot air. For example, the cooling device 100 may be configured and arranged to remove hot air from the case or to blow cool air into the case. The cooling device 100 may also be configured and arranged to remove hot air from a heat exchanger of a heat generating element, for example a CPU, a GPU or a mass storage drive, or to blow cool air onto the heat generating element.

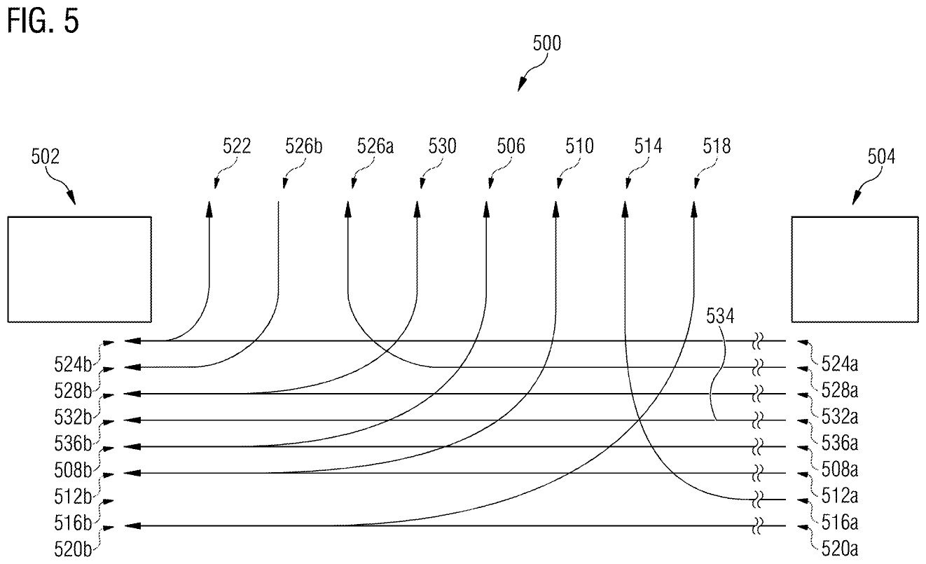

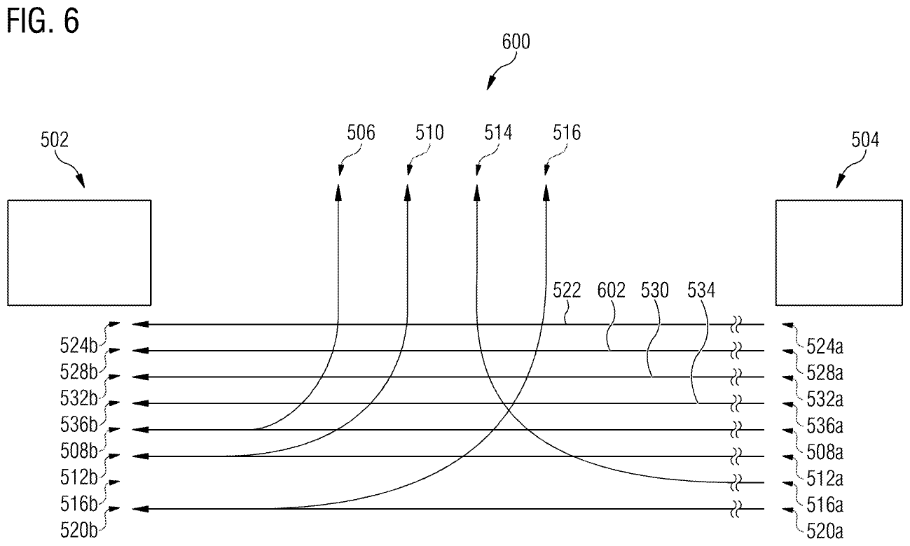

The cooling device 100 further comprises a wiring 106 arranged atop of the fan body 102 in FIG. 1. The wiring 106 comprises a female connector 108 show left in FIG. 1 and a male connector 110 shown right in FIG. 1. The wiring 106 further comprises wiring arrangements configured to provide electrical power and control signals to the cooling device 100. The wiring arrangements are described in more detail below with reference to FIGS. 5 and 6. A first line of wires 112 connects the female connector 108 to the male connector 110. A second line of wires 114 connects the first line of wires 112 to the cooling device 100. The first and second lines 112, 114 are arranged to form a T-shape. However, the first and second lines 112, 114 may also be arranged in an L-shape or form a triangle.

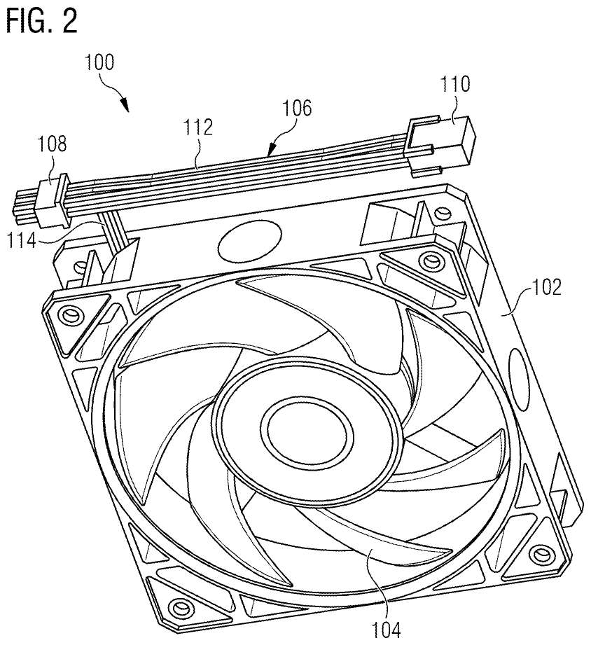

FIG. 2 is a schematic oblique top view of the cooling device 100 according to FIG. 1.

As can be seen in FIG. 2 the second line of wires 114 extends from a top surface of the fan body 102 of the cooling device 100 towards the first line of wires 112 According to the present embodiment, the second line of wires 114 is fixed to the cooling device 100. However, it is also possible to detachably connect the second line of wires 114 to the cooling device 100, for example by a pair of connectors.

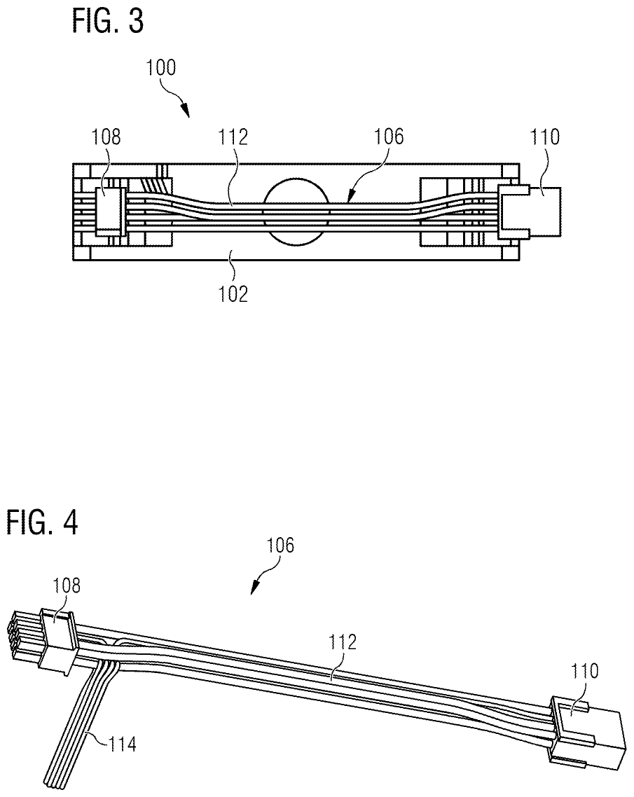

FIG. 3 is a schematic top view of the cooling device 100 according to FIG. 2.

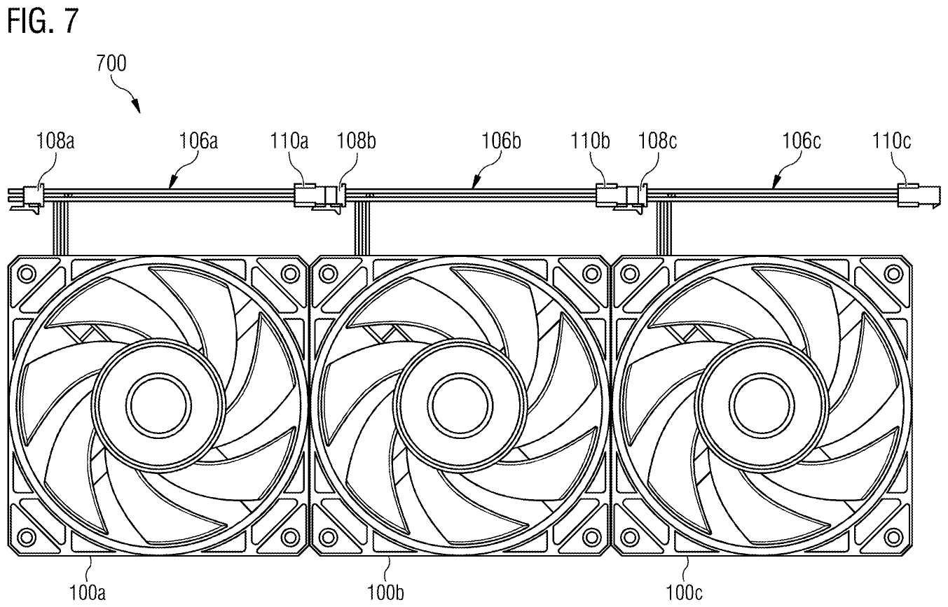

The first line of wires 112 extends over the complete width of the fan body 102, i.e. from left to right in FIG. 3. The male connector 110 is arranged such that it extends over the right side of the fan body 102 in FIG. 3 while the male connector 108 is arranged such that it is flush with the left side of fan body 102 in FIG. 3. This arrangement allows two or more cooling devices 100 to be connected in series as is described below with reference to FIG. 7.

FIG. 4 is a schematic view of the wiring 106 of the cooling device 100 according to FIGS. 1 to 3.

The male connector 108 is shown to the left of FIG. 4 and the male connector 110 is shown to the right of FIG. 4. The male connector 108 and the male connector 110 are connected by the first line of wires 112. The second line of wires 114 branches off from that first line of wires 112. It depends on the specifics of the cooling device 100 which wires of the first line of wires 112 branch off and which wires of the first line of wires 112 simply connect the male and female connectors 108, 110. The wiring 106 is detailed below with reference to FIGS. 5 and 6. In particular, the wiring 106 of the cooling device 100 may be any of the wiring 500, 600 according to the FIGS. 5 and 6.

FIG. 5 is a schematic view of a wiring 500 of a cooling device 100 according to an embodiment.

The wiring 500 comprises a female connector 502 having eight pins arranged on the left in FIG. 5, and a male connector 504 having eight pins arranged on the right in FIG. 5. The male connector 504 may be connected to a power supply and to one or more control units, for example arranged a mother board of a personal computer. The connection between the male connector 504 and the mother may either be direct or indirect, i.e. via an extension cable or a wiring 500 of another cooling device 100 when multiple cooling devices 100 are connected in series.

A first wire arrangement 506 connects a first pin 508a of the male connector 504 with a first pin 508b of the female connector 502. A branch of the first wire arrangement 506 electrically connects to the body 102 of the cooling device 100 for connecting the cooling device 100 unit to the ground. A second wire arrangement 510 connects a second pin 512a of the male connector 504 with a second pin 512b of the female connector 502. A branch of the second wire arrangement 510 electrically connects to the body 102 of the cooling device 100 for providing an electrical current having a voltage of +12 V to an electrical drive of the cooling device 100.

A third wire arrangement 514 connects a third pin 516 of the male connector 504 with the body 102 of the cooling device 100. The cooling device 100 is configured to send a sensor signal to its control unit via the third wire arrangement 514. For example, the control signal may be a tachometer signal of a speed sensor of a fan that is send to a fan control unit via the third wire arrangement 514. A fourth wire arrangement 518 connects a fourth pin 520a of the male connector 504 with a fourth pin 520b of the female connector 502. A branch of the fourth wire arrangement 518 electrically connects to the body 102 of the cooling device 100. The cooling device 100 is configured to receive a control signal from the control unit via the fourth wire arrangement 518. The control signal may be a pulse width modulation signal for controlling the speed of a fan.

A fifth wire arrangement 522 connects a first pin 524a of the male connector 504 with a fifth pin 524b of the female connector 502. A branch of the fifth wire arrangement 522 electrically connects to a body 102 of the cooling device 100 for providing an electrical current having a voltage of +5 V to an A-RGB lighting unit of the cooling device 100.

A sixth wire arrangement 526a electrically connects a second pin 528a of the male connector 504 to the A-RGB lighting unit. The A-RGB lighting unit is configured to receive a digital input signal via the sixth wire arrangement 526a and the second pin 528a of the male connector 504. The digital input signal controls the A-RGB lighting unit, in particular a color of the light emitted by the A-RGB lighting unit. A seventh wire arrangement 526b electrically connects a fifth pin 528b of the female connector 502 to the A-RGB lighting unit. The A-RGB lighting unit is configured to send a digital output signal via the seventh wire arrangement 526b and the second pin 528b of the female connector 502. The digital output signal may be identical to the digital input signal received by the A-RGB lighting unit. According to this embodiment, when two or more cooling devices 100 to be connected in series the A-RGB lighting unit of all cooling devices 100 in the series will receive the same digital input signal. In particular, it is possible to multiplex the digital input signal, such that each A-RGB lighting unit can be individually controlled. Alternatively, the A-RGB lighting unit may be configured to modify the digital input signal in order to generate the digital output signal.

An eighth wire arrangement 530 connects a seventh pin 532a of the male connector 504 with a seventh pin 532b of the female connector 502. A branch of the eighth wire arrangement 530 electrically connects to the body 102 of the cooling device 100 for connecting the A-RGB lighting unit to a ground. An additional wire arrangement 534 connects an eighth pin 536a of the male connector 504 with an eighth pin 536b of the female connector 502.

FIG. 6 is a schematic view of a wiring 600 of a cooling device 100 according to another embodiment.

The cooling device 100 according to FIG. 6 is distinguished form the cooling device 100 according to FIG. 5 in not having the A-RGB lighting unit. Consequently, the wiring 500 of the cooling device 100 according to FIG. 6 does not comprise branches for providing control signals and electrical power to the A-RGB lighting unit. According to this embodiment, a tenth wire arrangement 602 connects the sixth pin 528a of the male connector 504 to the sixth pin 528b of the female connector 502.

When several cooling devices 100 are connected in series, the cooling device 100 according to FIG. 5, i.e. comprising an A-RGB lighting unit, can receive the digital input signal even when the cooling unit according to the present embodiment is arranged before the cooling device 100 according to FIG. 5 in the series.

FIG. 7 is a schematic view of a cooling system 700 for a personal computer according to an embodiment.

The cooling system 700 according to FIG. 7 comprises three cooling devices 100a, 100b, 100c according to FIGS. 1 to 6. The three cooling devices 100a, 100b, 100c are arranged in a single row directly next to each other. In this arrangement, the cooling devices 100a, 100b, 100c may for example be mounted on a side of a case of the personal computer. Although three cooling devices 100a, 100b, 100c are shown in FIG. 7, the cooling system 700 may comprise any number of cooling devices 100a, 100b, 100c that may realistically be arranged inside the case of the personal computer.

The male connector 110a of the leftmost cooling device 100a is connected to the male connector 108b of the cooling device 100b arrange in the middle of the cooling system 700. The male connector 110b of the middle cooling device 100b is connected to the male connector 108c of the rightmost cooling device 100c. Thereby, all three cooling devices 100a, 100b, 100c are connected by a single line of wires formed by the wirings 106a, 106b, 106c of the cooling devices 100a, 100b, 100c, and thus all three cooling devices 100a, 100b, 100c are connected in series. All cooling devices 100a, 100b, 100c can be connected to a power supply and/or a fan control unit at once by either connecting the right most male connector 110 or the leftmost female connector 108 to the power supply and/or the fan control unit. This arrangement produces significantly less cable clutter that a known arrangement using a cable splitter.

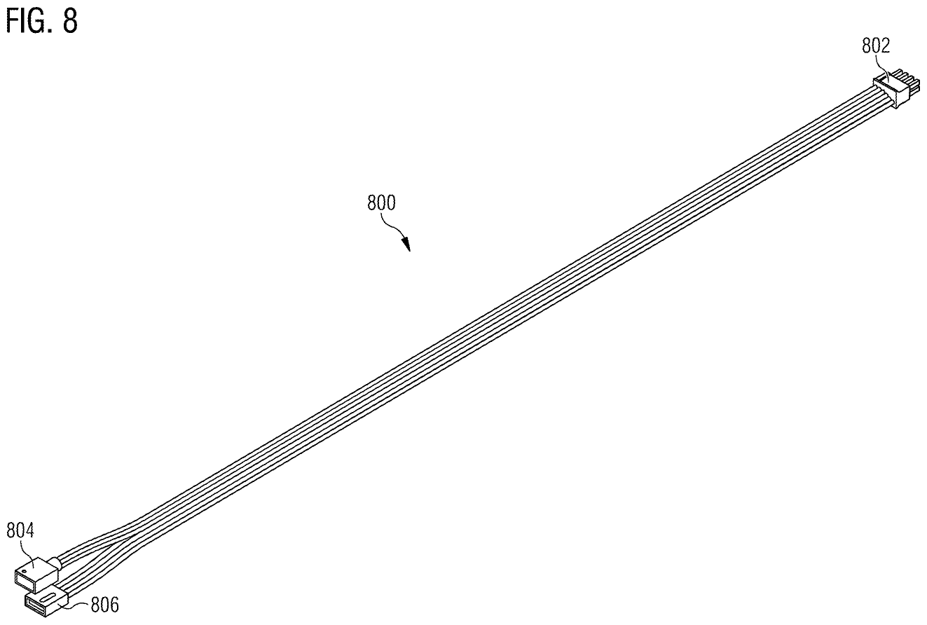

FIG. 8 is a schematic view of a cable 800 of the cooling system 700 according to FIG. 7.

The cable 800 comprises a first connector 802 that is configured to connect the one of the connectors 108, 110 of the wiring 106 of the cooling device 100. The cable 800 further comprises a second connector 806 that is configured to connect to at least a first power supply, and third connector 804 configured to connect to a second power supply and to a lighting control unit. The second connector 806 may also be configured to connect to a control unit configured to control the cooling device 100, for example a fan control unit or a pump control unit.

In the present embodiment, the first connector 802 is exemplary formed as a male connector having eight pins. The eight pins of the first connector correspond to the eight pins 508a, 508b, 512a, 512b, 516, 520a, 520b, 524a, 524b, 528a, 528b, 532a, 532b, 536a, 536b of the wiring 500, 600 according to FIGS. 5 and 6. The second connector 806 is a female connector having four pins. The four pins of the second connector correspond to the first to fourth pins 508a, 508b, 512a, 512b, 516, 520a, 520b of the wiring 500, 600 according to FIGS. 5 and 6. The third connector 804 is a female connector having three pins corresponding to the fifth to seventh pins 524a, 524b, 528a, 528b, 532a, 532b, 536a, 536b of the wiring 500, 600 according to FIGS. 5 and 6. The cable 800 according to FIG. 8 can for example be used to connect a cooling device 100 having the wiring 500, 600 according to FIGS. 5 and 6 to a mother board of a personal computer.

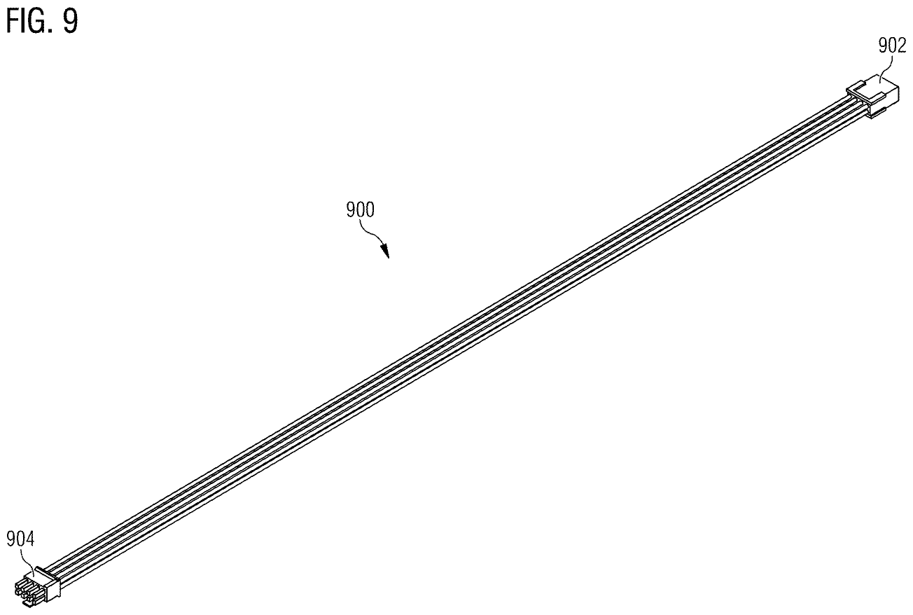

FIG. 9 is a schematic view of another cable of the cooling system 700 according to FIG. 7.

The cable according to FIG. 9 comprises a male connector 902 that is configured to connect the male connector 108 of the wiring 106 of the cooling device 100, and a male connector 904 that is configured to connect the male connector 110 of the wiring 500, 600 of the cooling device 100.

In the present embodiment, the male and female connectors 902,904 are exemplary formed as having eight pins each. The eight pins correspond to the eight pins 508a, 508b, 512a, 512b, 516, 520a, 520b, 524a, 524b, 528a, 528b, 532a, 532b, 536a, 536b of the wiring 500, 600 according to FIGS. 5 and 6. The cable according to FIG. 9 can for example be used as an extension between different cooling devices 100 in order to connect the cooling devices 100 100 in series.

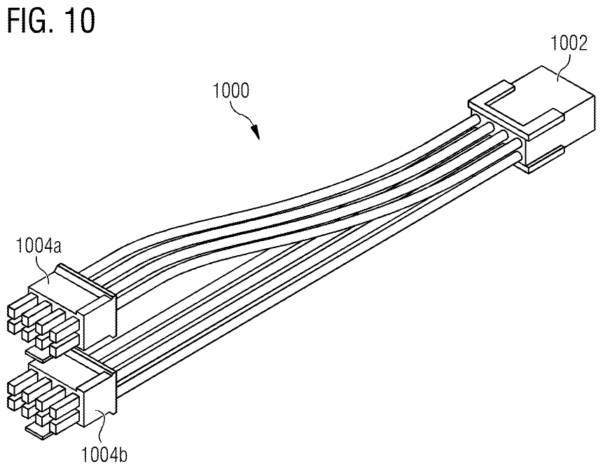

FIG. 10 is a schematic view of another cable 1000 of the cooling system 700 according to FIG. 7.

The cable 1000 according to FIG. 10 comprises a first connector 1002 that is configured to connect the one of the connectors 108, 110 of the wiring 106 of the cooling device 100, and two second connectors 1004a, 1004b configured to connect the other connector 110, 108 of the wiring 106 of the cooling device 100. In the present embodiment, the first connector 1002 is exemplary formed as a male connector having eight pins. The second connectors 1004a, 1004b are exemplary formed as a male connector having eight pins each. The eight pins correspond to the eight pins 508a, 508b, 512a, 512b, 516, 520a, 520b, 524a, 524b, 528a, 528b, 532a, 532b, 536a, 536b of the wiring 500, 600 according to FIGS. 5 and 6. The cable 1000 according to FIG. 10 can for example be used as a branch between two different series of cooling devices 100.

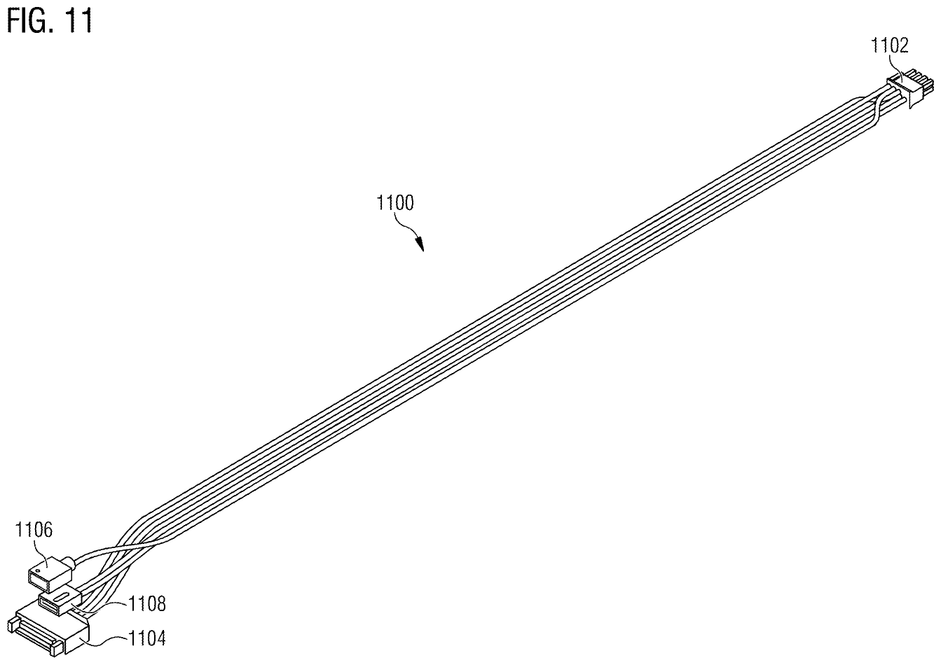

FIG. 11 is a schematic view of a cable 1100 of the cooling system 700 according to FIG. 7.

The cable comprises a first connector 1102 that is configured to connect the one of the connectors of the wiring 106 of the cooling device 100. The cable further comprises a second connector 1104 that is configured to connect to a power supply, a third connector 1106 configured to connect to a control unit for controlling the lighting unit, and a forth connector 1108 configured to connect to a control unit for controlling the cooling device 100.

In the present embodiment, the first connector 1102 is exemplary formed as a male connector having eight pins. The eight pins of the first connector correspond to the eight pins 508a, 508b, 512a, 512b, 516, 520a, 520b, 524a, 524b, 528a, 528b, 532a, 532b, 536a, 536b of the wiring 500, 600 according to FIGS. 5 and 6. The second connector 1104 is exemplary formed as a SATA connector. The pins of the second connector 1104 correspond to the first, second, fifth, and seventh pins 508a, 508b, 512a, 512b, 524a, 524b, 532a, 532b of the wiring 500, 600 according to FIG. 5 and 6. In other words, first connector provides the connection to the power supply of the cooling device 100 and the power supply of the lighting unit.

The third connector 1106 is a female connector having a single pin connected to a wire of the cable 1100. The connected pin of the fourth connector 1106 corresponds to the sixth pin 528a, 528b of the wiring 500, 600 according to FIGS. 5 and 6. The fourth connector 1108 is a female connector having two pins connected to wires of the cable 1100. The two connected pins of the third connector 1106 correspond to the third and fourth pins 516, 520a, 520b of the wiring 500, 600 according to FIGS. 5 and 6.

The cable according to FIG. 11 can for example be used to connect a cooling device 100 having the wiring 500, 600 according to FIGS. 5 and 6 to a mother board of a personal computer. Since the power supply is handled by a SATA connector, more electrical power can be supplied to the cooling devices 100 of the cooling system 700.

The proposed cooling system 700 may comprise any feasible number of the cooling devices 100 described above with reference to FIGS. 1 to 6. The proposed cooling system 700 may further comprise any feasible number of cables described above with reference to FIGS. 8 to 11.

Identical or similarly acting elements are designated with the same reference signs in all Figures. As used herein the term “and/or” includes any and all combinations of one or more of the associated listed items. Individual features of the embodiments and all combinations of individual features of the embodiments among each other as well as in combination with individual features or feature groups of the preceding description and/or claims are considered disclosed.

1. A cooling system for a personal computer, comprising
at least one cooling device using electrical power and having a body and a wiring, the wiring comprising a male connector, a female connector, at least one first wire arrangement, and at least one second wire arrangement;
wherein the first and second wire arrangements electrically connect the male connector to the cooling device, the female connector to the cooling device, and the male connector to the female connector;
wherein the first wire arrangement is configured to electrically connect the cooling device to a ground; and
wherein the second wire arrangement is configured to electrically connect the cooling device to a power supply.

2. The cooling system according to claim 1, wherein the wiring is arranged in one of a T-shape or an L-Shape comprising a first line of wires between the male connector and the female connector, and a second line of wires extending from the first line of wires and connecting the first line of wires with a body of the cooling device.

3. The cooling system according to claim 1, wherein the cooling device comprises a fan; and wherein the second wire arrangement is configured to electrically connect the fan to the power supply.

4. The cooling system according to claim 3, wherein the wiring comprises at least one third wire arrangement, and at least one fourth wire arrangement; wherein the third wire arrangement electrically connects the male connector to the cooling device, the fourth wire arrangement electrically connects the male connector to the body of the cooling device, the female connector to the body of the cooling device, and the male connector to the female connector; wherein the third wire arrangement is configured to electrically connect the cooling device to a fan control unit, and to transmit a tachometer signal of a speed sensor of the fan to the fan control unit; and wherein the fourth wire arrangement is configured to electrically connect the cooling device to the fan control unit, and to transmit a pulse width modulation signal from the fan control unit to the fan.

5. The cooling system according to claim 1, wherein the cooling device comprises a coolant pump configured to pump a liquid coolant; and wherein the second wire arrangement is configured to electrically connect the coolant pump to the power supply.

6. The cooling system according to claim 1, wherein the cooling device comprises a lighting unit configured to illuminate the cooling device; wherein the wiring comprises at least one fifth wire arrangement; wherein the fifth wire arrangement connects the male connector to the lighting unit, the female connector to the lighting unit, and the male connector to the female connector; and wherein the fifth wire arrangement is configured to electrically connect the lighting unit to a second power supply.

7. The cooling system according to claim 6, wherein the lighting unit is configured for A-RGB lighting, to receive a digital input signal for controlling the A-RGB lighting, and to provide a digital output signal; wherein the wiring comprises at least one sixth wire arrangement, at least one seventh wire arrangement, and at least one eighth wire arrangement; wherein the sixth wire arrangement is configured to electrically connect the lighting unit to a lighting control unit configured to provide the digital input signal; wherein the seventh wire arrangement is configured to electrically connect the lighting unit to a target of the digital output signal; and wherein the eighth wire arrangement is configured to electrically connect the lighting unit to the ground.

8. The cooling system according to claim 6, wherein the lighting unit is configured for RGB lighting, and to receive a first input signal for controlling a red element of the RGB lighting, a second input signal for controlling a green element of the RGB lighting, and a third input signal for controlling a blue element of the RGB lighting; wherein the wiring comprises at least one ninth wire arrangement, at least one tenth wire arrangement, and at least one eleventh wire arrangement; wherein the ninth wire arrangement is configured to electrically connect the lighting unit to a lighting control unit configured to provide the first input signal; wherein the tenth wire arrangement is configured to electrically connect the lighting unit to a lighting control unit configured to provide the second input signal; and wherein the eleventh wire arrangement is configured to electrically connect the lighting unit to a lighting control unit configured to provide the third input signal.

9. The cooling system according to claim 7, comprising a cable having a first connector configured to connect either to the female connector of the wiring or to connect to male connector of the wiring, a second connector configured to connect to at least the first power supply, and a third connector configured to connect to the lighting control unit.

10. The cooling system according to claim 9, wherein the second connector is a SATA power connector.

11. The cooling system according to claim 10, comprising a fourth connector configured to connect to the fan control unit.

12. The cooling system according to claim 1, comprising a cable having a male connector configured to connect to the female connector of the wiring, and a female connector configured to connect to the male connector of the wiring.

13. The cooling system according to claim 1, comprising a controller configured to send a pulse width modulation signal and to receive a tachometer signal.

14. The cooling system according to claim 1, comprising a controller configured to send a digital input signal.

15. The cooling system according to claim 13, wherein the controller comprises the first power supply and/or the second power supply.
